(19) United States
(12) Patent Application Publication
(10) Pub. No.: US 2016/0230310 A1
(43) Pub. Date: Aug. 11, 2016

(54) PROCESS OF MANUFACTURING PURE POROUS DIAMOND

(71) Applicant: Saeed Alhassan ALKHAZRAJI, Abu Dhabi (AE)

(72) Inventor: Saeed Alhassan ALKHAZRAJI, Abu Dhabi (AE)

(21) Appl. No.: 15/018,928

(22) Filed: Feb. 9, 2016

Related U.S. Application Data
(60) Provisional application No. 62/113,549, filed on Feb. 9, 2015.

(51) Int. Cl. C30B 25/00; C23C 16/01; C23C 16/27; C30B 29/04; C30B 29/66

(52) U.S. Cl. CPC C30B 25/00; C30B 29/04; C30B 29/66; C23C 16/27; C23C 16/01

(57) ABSTRACT

There is provided a process for manufacturing a porous diamond having a tridimensional (3D) structure, the process comprising the steps of a) using a porous substrate with a defined porosity size to deposit and grow diamond material having a controlled thickness, thus forming a unit consisting of the 3D porous diamond coated on the porous substrate; and b) removing the porous substrate to obtain a pure synthetic porous 3D diamond.

### FIELD OF THE INVENTION

The present invention relates to a process of manufacturing synthetic diamonds, and more particularly to a process of manufacturing pure synthetic solid state 3-dimensional structure porous diamond.

### BACKGROUND OF THE INVENTION

Diamond has been one of the most fascinating allotropes of elemental carbon. Synthetic diamond has attracted great deal of attention because it can be fabricated at relatively low cost with good control over morphology and size. A recent advancement in the field is the process of making a porous diamond through high temperature and high pressure route using porous carbon as precursor. The major disadvantage for this process of producing diamond aerogels is that the resultant porous diamond is a composite of nanosize only (powder form). Also, the manufactured product is a composite of diamond and other material used as substrate during the manufacturing process. Therefore, this method is not suitable for producing larger size monoliths of pure porous diamond.

Moreover, in order to produce porous diamond of large dimensions (centimeter and above), and in particular a 3D structure porous diamond, a chemical vapor deposition or a plasma deposition method can be a suitable option. However, a standalone, large size, porous diamond has never been fabricated in the past. Moreover, the final 3D porous diamond has never been disclosed without a substrate.

### SUMMARY OF THE INVENTION

Therefore it is an object of the present invention to provide a method for manufacturing a solid state 3D structure of porous diamond with a required dimension and without having any substrate.

It is also another object of the present invention to provide a method for producing a porous diamond having controlled pores of high density and without performing complicated steps like those already know in the art.

As a first aspect of the present invention, there is provided a process for manufacturing a porous diamond having a tridimensional (3D) structure, the process comprising the steps of
a) using a porous substrate with a defined porosity size to deposit and grow diamond material having a controlled thickness, thus forming a unit consisting of the 3D porous diamond coated on the porous substrate; and
b) removing the porous substrate to obtain a pure synthetic porous 3D diamond.

Typically, the porous substrate used for a deposition and growth of the diamond is made from a material selected from metallic and non metallic material. Preferably, the porous substrate material is selected from a group consisting of silicon, molybdenum, tungsten, titanium, silicon carbide, beryllium oxide, nickel, platinum, cobalt, iridium and iron. More preferably, wherein the porous substrate material is selected from silicon, titanium, tungsten, platinum and cobalt, being the most preferable titanium.

Typically, the pores of the substrate having spherical, cylindrical, tubular or rectangular geometry. Preferably, the pores of the substrate have a spherical geometry.

The deposition process of the diamond on the porous substrate according to the present invention can be performed using any conventional deposition techniques already known in the art. Examples of deposition techniques that can be used in the present invention are but not limited to, chemical vapour deposition (CVD), Physical vapour deposition (PVD), Arc jet based CVD, Hot filament CVD (HFCVD), Microwave assisted chemical vapor deposition (MWCVD), Microplasma, Radio Frequency Plasma Chemical Vapour Deposition (RFPCVD), Direct current plasma chemical vapor deposition (DC-PCVD), electron cyclotron resonance (ECR), plasma CVD (ECR-PCVD), Combustion flame CVD and Epitaxy deposition.

In a preferred embodiment of the present invention, the deposition process of diamond on the porous substrate is performed using chemical vapor deposition CVD.

In an embodiment of the present invention, the porous substrate is removed by a process selected from a thermal decomposition, oxidative decomposition, acidic etching and basic etching. Preferably, the porous substrate is removed by immersing the units into a chemical solution for at least 2 hours.

In a still preferred embodiment, the removal process of the substrate of the present invention can be performed at a temperature ranging from room temperature to a temperature below the boiling point of the solution. Preferably at a temperature ranging from 30° C. to the temperature below the boiling point of the solution, more preferably at a temperature ranging from 50 to 75° C. Within this range of temperature, the removal process of the substrate is accelerated and therefore the timing of the process decreases drastically.

In a preferred embodiment of the present invention, the chemical solution used during the removal process of the substrate is an aqueous acidic chemical solution. Preferably, the chemical solution is a hydrogen chloride solution or a sulphuric acid solution. The concentration of the acidic solution used in the present invention should preferably be higher. This is another factor to accelerate the process of the removal of the substrate.

In a preferred embodiment of the present invention, the concentration of the aqueous acidic solution is in the range of 1 to 10M (or mol/L), preferably in the range of 5 to 10 M (or mol/L).

It is to be understood that the molar concentration is expressed as mol/L (Molar or M). This is also referred to as molarity, which is the most common method of expressing the concentration of a solute in a solution. Molarity is defined as the number of moles of solute dissolved per liter of solution (mol/L=M)

In another preferred embodiment, the pure 3D porous diamond obtained is washed with water to remove any excess of the chemical solution and/or the substrate residues.

In a still preferred embodiment of the present invention, the removal step b) is repeated one or more times to ensure the complete removal of the substrate, and wherein the 3D porous diamond is previously washed with water before repeating the removal process of step b).

The obtained pure porous diamond according to the process of the present invention is a porous diamond product with a controlled thickness and size. The size of the pure diamond can be in the range of 1 cm to 10 cm in size. Larger sizes are possible and only limited by the size of the substrate 100 used and the capacity of chambers used for diamond growth.

### BRIEF DESCRIPTION OF THE DRAWINGS

FIGS. 1a and 1b illustrates a plan view and cross section, respectively of a porous substrate to be used for deposition and growth of porous diamond, in accordance with an embodiment of the present invention.

FIG. 2 illustrates a cross section of a portion of diamond growth on the substrate, in accordance with an embodiment of the present invention.

FIGS. 3a and 3b illustrate a plan view and a cross-section view of a portion of a pure diamond material after removal of the substrate, in accordance with an embodiment of the present invention.

### DETAILED DESCRIPTION OF THE INVENTION

The present method proposes the fabrication of porous pure diamond with controlled porosity, chemistry and consequently physical properties through a two steps process.

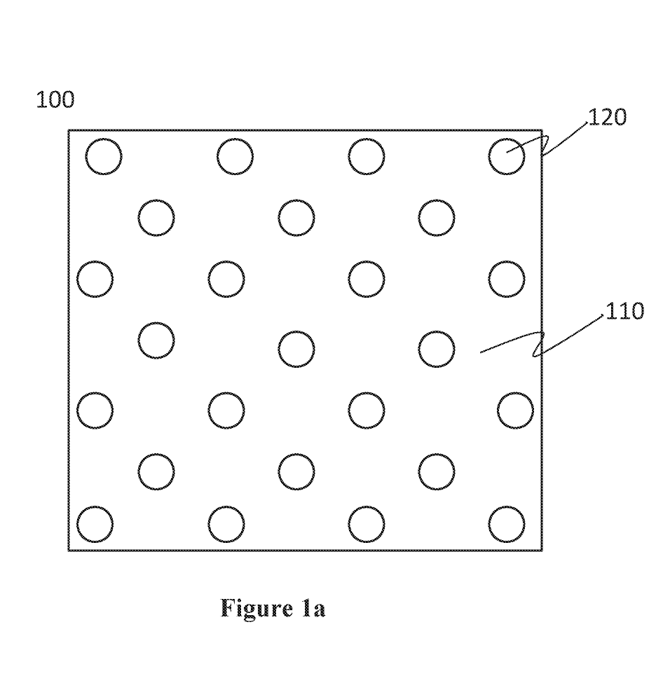

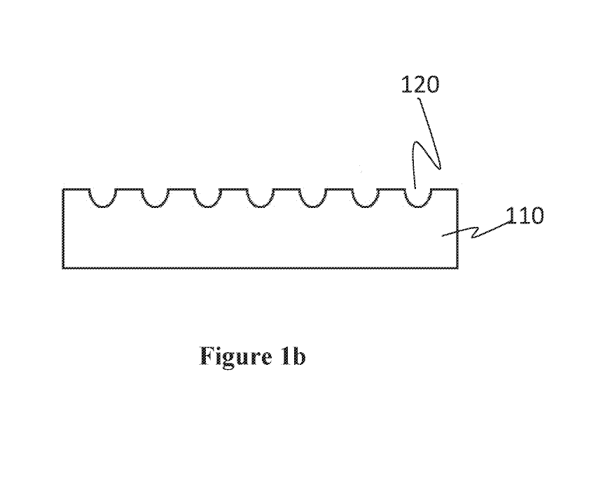

As illustrated in FIGS. 1a and 1b, a porous substrate 100 having a base 110 with specific porosity 120 is used to deposit and grow diamond films with controlled thickness. The substrate base 110 can have different shape and geometry depending on the final geometry of the diamond needed to be manufactured. Examples of a type of shape or geometry of the substrate base 110 are, but not limited to, square, rectangular or circular.

The porous substrate 100 may be made from a material selected from metallic and non metallic material. Preferably, the substrate material is selected from a group consisting of silicon, molybdenum, tungsten, titanium, silicon carbide, beryllium oxide, nickel, platinum, cobalt, iridium and iron, or combinations thereof. More preferably, wherein the porous substrate material is selected from silicon, titanium, tungsten, platinum and cobalt, being the most preferable titanium.

The pores of the substrate 120 are arranged along the surface of the substrate base 110. The arrangement type and the size of the pore 120 are previously defined and controlled depending on the type and shape of the porous diamond needed to be manufactured. Examples of the shape of the pores are, but not limited, circular, square, star shape. The pores of the substrate 120 can be defined from nanoscale to microscale to including macroscale. Preferably, the size of the pores 120 are within the ranges of 1 nm-4000 nm, preferably from 5 nm to 400 nm and more preferably from 10 to 100 nm.

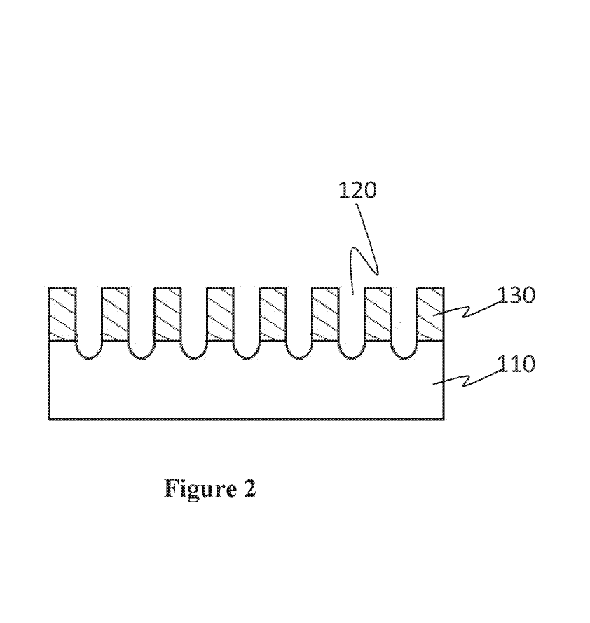

A diamond layer 130 is coated on the porous substrate 100 as illustrated in FIG. 2. The coating process may be performed using conventional methods suitable for the deposition of diamond on a substrate. Examples of such coating or deposition processes are but not limited to, chemical vapour deposition (CVD), Physical vapour deposition (PVD), Arc jet based CVD, Hot filament CVD (HFCVD), Microwave assisted chemical vapor deposition (MWCVD), Microplasma, Radio Frequency Plasma Chemical Vapour Deposition (RFPCVD), Direct current plasma chemical vapor deposition (DC-PCVD), electron cyclotron resonance (ECR), plasma CVD (ECR-PCVD), Combustion flame CVD and Epitaxy deposition.

In a preferred embodiment the deposition and growth of the diamond is performed using the chemical vapour deposition. The process is preferably performed a pressure ranging from 10 to 100 Torr, at a temperature raging from 300 to 1500° C., preferably from 700 to 1300 ° C.

In another preferred embodiment of the present invention, hydrocarbon gases such as methane (CH₄) or acetylene (C₂H₂) are used as a source or precursor for depositing and growth of diamond layer. The injection of hydrocarbon gas is preferably performed using a mixture of said hydrocarbon gas with hydrogen gas. The preferred ratio of said gas mixture is from 1 to 10% of the hydrocarbon gas with respect to hydrogen gas. By injecting more than 10% of hydrocarbon gas may create defects in the diamond during its formation.

By adjusting the parameters and conditions of the CVD process, 3D diamond is formed having a controlled thickness and porosity. During the deposition and growth of the diamond, the porosity of the later adopts the same geometry and shape as the pores of the substrate. This is very advantageous since it is easier to manufacture porous diamond material with controlled thickness and porosity by simply choosing the porous substrate to be used.

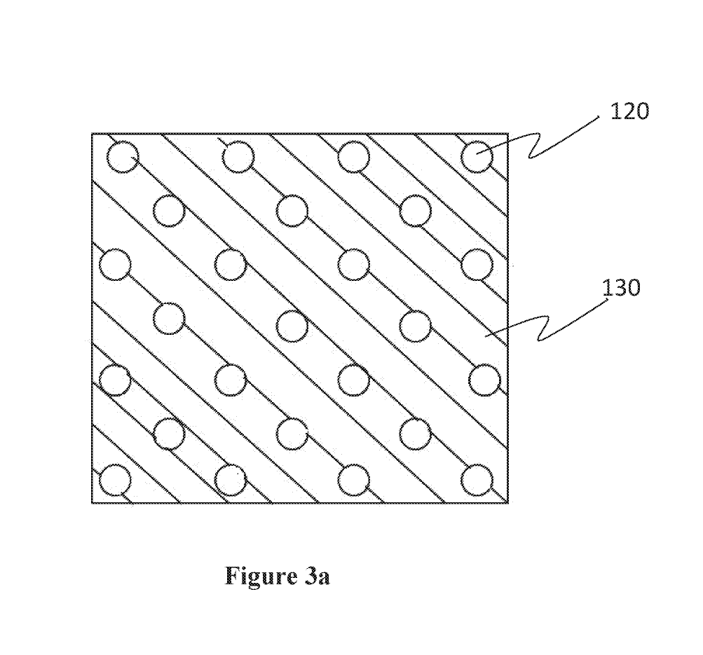

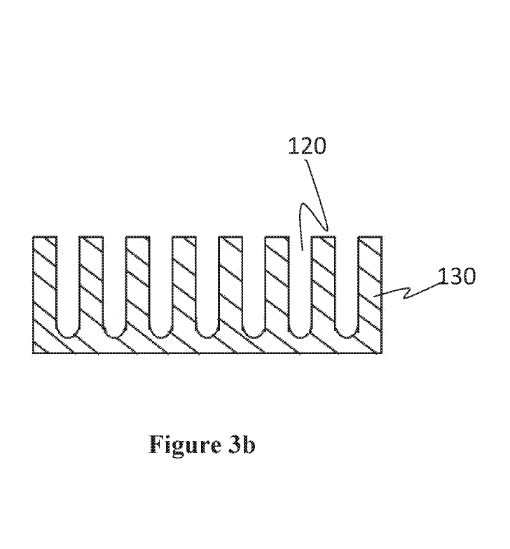

The second step of the process of the present invention is the removal of the porous substrate 100. Said porous substrate 100 is removed or etched out via several methods including but are not limiting to, a thermal decomposition, oxidative decomposition, acidic etching and basic etching. As illustrated in FIGS. 3a and 3b, the final product is a synthetic porous diamond 130 having the same size and geometry of the pores 120 of the substrate but without being coated to any substrate 100.

Preferably, the porous substrate 100 is removed by immersing the unit into a chemical solution for at least 2 hours. The removal process of the substrate 100 of the present invention can be performed at a temperature ranging from room temperature to a temperature below the boiling point of the solution. Preferably at a temperature ranging from 30° C. to the temperature below the boiling point of the solution, more preferably at a temperature ranging from 50 to 85° C. Within this range of temperature, the removal process of the substrate 100 is accelerated and therefore the process time decreases drastically.

In a preferred embodiment of the present invention, the chemical solution used during the removal process of the substrate 100 is an aqueous acidic chemical solution. Preferably, the chemical solution is a hydrogen chloride solution or a sulphuric acid solution. The concentration of the acidic solution used in the present invention should preferably be higher. Using higher concentration of acidic solution also help to accelerate the process of the removal of the substrate. The concentration of the aqueous acidic solution is preferably in the range of 1 to 10M, more preferably in the range of 5 to 10 M.

In another preferred embodiment, the pure 3D porous diamond obtained is washed with water to remove any excess of the chemical solution and/or the substrate residues.

In a still preferred embodiment of the present invention, the removal step b) is repeated one or more times, preferably two or three times to ensure the complete removal of the substrate and any residues generated from the removal step. The 3D porous diamond is previously washed with water, preferably distilled water, before repeating the removal process of the substrate as described in step b).

The obtained pure porous diamond according to the process of the present invention is a porous diamond product with a controlled thickness and size. The size of the pure diamond can be in the range of 1 cm to 10 cm.

The manufactured product is a pure porous diamond free of any substrate. The final product is large size porous diamond with many of desirable properties that make it suitable for many applications including jewelry.

The process of the present invention can obtain a void at micro level which cannot be seen by eyes or it can also create voids at macro level which is visible to the eyes. The substrate used to deposit the diamond films is then eliminated through the pores leaving a pure porous diamond with air inside the pores resulting from the process. The process according to the present invention can obtain synthetic porous diamond in a solid state of dimensions of up to 10 cm.

The method of the present invention is capable of producing a solid state 3-dimensional structure with any desired porosity. The produced synthetic porous diamond takes the form and the porosity of the substrate used. The process for manufacturing porous diamond without substrate and with special geometry, shape and porosity, exhibit superior mechanical strength and thus is suitable for many applications.

For example, the 3D pure diamond obtained without substrate according to the process of the present invention can be used to enhance and reinforce material and final structures. For example, in the fabrication of microelectronic structures that should be robust enough for packaging and transportation, or for structural application skeleton to reinforce other materials, such as plastics. The enhanced mechanical, thermal, electrical, acoustic properties of 3D porous diamond manufactured according to the present invention offers a wide range of applications, such as shock and impact energy absorbers, dust and fluid filters, engine exhaust mufflers, porous electrodes, high temperature gaskets, heaters, heat exchangers, catalyst supports, construction materials and biomaterials.

While the invention has been made described in details and with reference to specific embodiments thereof, it will be apparent to one skilled in the art that various additions, omissions, and modifications can be made without departing from the spirit and scope thereof.

In particular, although the description has specified certain steps and materials that may be used in the method of the present invention, those skilled in the art will appreciate that many modifications and substitutions may be made. Accordingly it intended that all such modifications, alterations, substitutions and additions be considered to fall within the spirit and scope of the invention.

What is claimed is:

1. A process for manufacturing a porous diamond having a tridimensional (3D) structure, the process comprising the steps of:
a) using a porous substrate with a defined porosity size to deposit and grow diamond material having a controlled thickness, thus forming a unit consisting of the 3D porous diamond coated on the porous substrate; and
b) removing the porous substrate to obtain a pure synthetic porous 3D diamond.

2. The process of claim 1 wherein the porous substrate is made from a material selected from metallic and non metallic material.

3. The process according to claim 1 wherein the porous substrate material is selected from a group consisting of silicon, molybdenum, tungsten, titanium, silicon carbide, beryllium oxide, nickel, platinum, cobalt, iridium and iron.

4. The process according to claim 3, wherein the porous substrate material is selected from silicon, titanium, tungsten, platinum and cobalt, preferably titanium.

5. The process according to claim 1, wherein the pores of the substrate having spherical, cylindrical, tubular or rectangular geometry.

6. The process according to claim 5, wherein the pores of the substrate has a spherical geometry.

7. The process according to claim 1 wherein the deposition of diamond on the porous substrate is performed using chemical vapor deposition CVD.

8. The process according to claim 1 wherein the porous substrate is removed by a process selected from a thermal decomposition, oxidative decomposition, acidic etching and basic etching.

9. The process according to claim 8, wherein the porous substrate is removed by immersing the units as defined in claim 1 into a chemical solution for at least 2 hours a temperature ranging from room temperature to a temperature below the boiling point of the solution.

10. The process according to claim 9, wherein the chemical solution is an aqueous acidic solution.

11. The process according to claim 9, wherein the chemical solution is a hydrogen chloride solution or a sulphuric acid solution.

12. The process according to claim 10, wherein the concentration of the aqueous acidic solution is in the range of 1 to 10M.

13. The process according to claim 8, wherein the pure 3D porous diamond obtained is washed with water to remove any excess of the chemical solution and/or the substrate residues.

14. The process according to claim 1 wherein the removal step b) is repeated one or more times to ensure the complete removal of the substrate, and wherein the 3D porous diamond is previously washed with water before repeating the removal process of step b).

15. The process according to claim 1 wherein the obtained pure porous diamond is in the range of 1 cm to 10 cm in size.
